(19) United States
(12) Patent Application Publication
(10) Pub. No.: US 2011/0266673 A1
(43) Pub. Date: Nov. 3, 2011

(54) INTEGRATED CIRCUIT PACKAGE STRUCTURE AND METHOD

(75) Inventor: CHUN-SHENG HU, Tu-Cheng (TW)

(73) Assignee: HON HAI PRECISION INDUSTRY CO., LTD., Tu-Cheng (TW)

(21) Appl. No.: 12/959,396

(22) Filed: Dec. 3, 2010

(30) Foreign Application Priority Data
Apr. 29, 2010 (CN) 201010159828.3

(51) Int. Cl. H01L 23/50; H01L 21/50

(52) U.S. Cl. 257/741; 438/113; 257/E23.079; 257/E21.499

(57) ABSTRACT

An integrated circuit package structure includes an integrated circuit (IC) module, a plastic encapsulation, and input/output pins. The IC includes a substrate configured with signal lines and input/output ports disposed at edges of the substrate, chips, and wires. The chips are mounted on surfaces of the substrate, and the wires connect the chips to the signals lines and the input/output ports. The plastic encapsulation encapsulates the IC module to form an encapsulation body including an upper surface, a lower surface, and side surfaces, and the input/output ports are exposed out of the encapsulation body. The input/output pins are disposed on the side surfaces and at least one of the upper surface and the lower surface of the encapsulation body, and correspondingly leads the input/output ports to the at least one of the upper surface and the lower surface of the encapsulation body.

### BACKGROUND

1. Technical Field

The disclosure relates to semiconductor packages, and particularly to an integrated circuit package structure and method.

2. Description of Related Art

In a ball grid array (BGA) package, inputs/outputs (I/O) of packaged integrated circuits (IC) are lead to surfaces of the BGA package via solder balls to form I/O pins, to connect external circuits. However, soldering problems of the solder balls may influence electrical characteristics of the I/O pins. In addition, height of the solder balls needs to be greater than height of the IC, thus, sizes of the solder balls are big, which limits amounts of the solder balls in the BGA package and further limits amounts of the I/O pins lead to the surface of the BGA package.

### BRIEF DESCRIPTION OF THE DRAWINGS

FIG. 1 is a schematic diagram of one embodiment of an integrated circuit package structure as disclosed.

FIG. 2 is a cross-section view taken along line A-A of one embodiment of the integrated circuit package structure of FIG. 1.

FIG. 3 is a schematic diagram of disposition of input/output pins on surfaces of the integrated circuit package structure of FIG. 1.

FIG. 4 is a cross-section view taken along line A-A of another embodiment of the integrated circuit package structure of FIG. 1.

FIG. 5 is a flowchart of one embodiment of an integrated circuit package method as disclosed.

FIG. 6 is a flowchart of one embodiment of disposing integrated circuits on a printed circuit board of an integrated circuit package method as disclosed.

FIG. 7 is a schematic diagram of disposition of integrated circuits on a printed circuit board of an integrated circuit package method as disclosed.

FIG. 8 is a schematic diagram of cutting an encapsulation body of an integrated circuit package method as disclosed.

### DETAILED DESCRIPTION

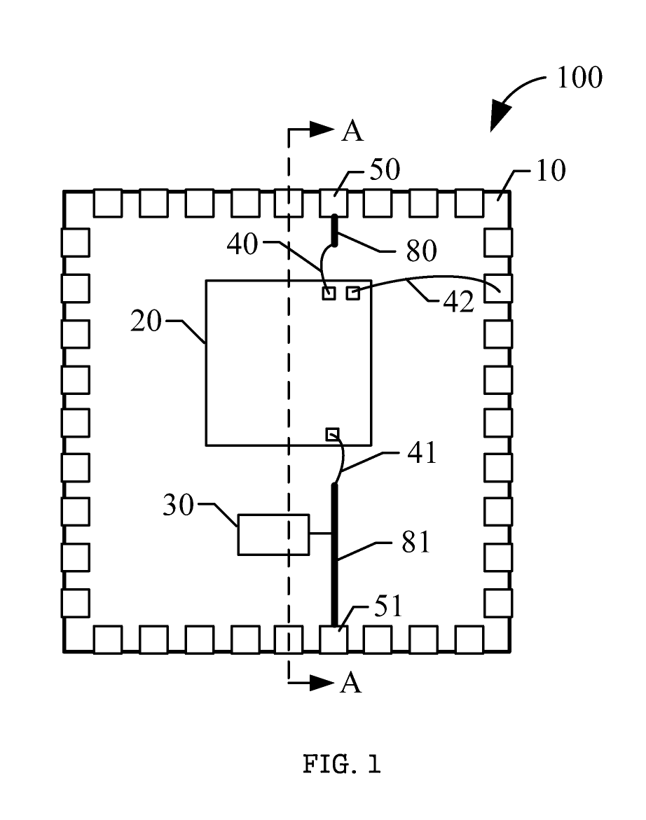

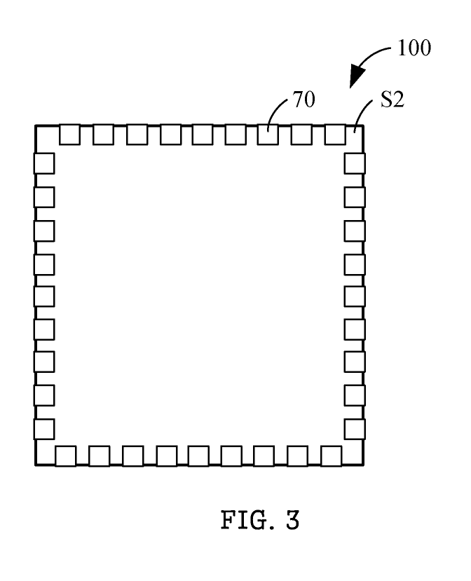

FIGS. 1 to 3 are schematic diagrams of one embodiment of an integrated circuit (IC) package structure 100 as disclosed. In one embodiment, the IC package structure 100 includes plastic encapsulations 60, 61, a plurality of input/output pins 70, 71, and an IC module 90. The IC module 90 includes a substrate 10, a plurality of chips 20, 21, a plurality of wires 40, 41, 42, 43, 44, a plurality of input/output ports 50, 51, and a plurality of signal lines 80, 81. In alternative embodiments, the IC module 90 further includes a plurality of passive components 30, 31, 32.

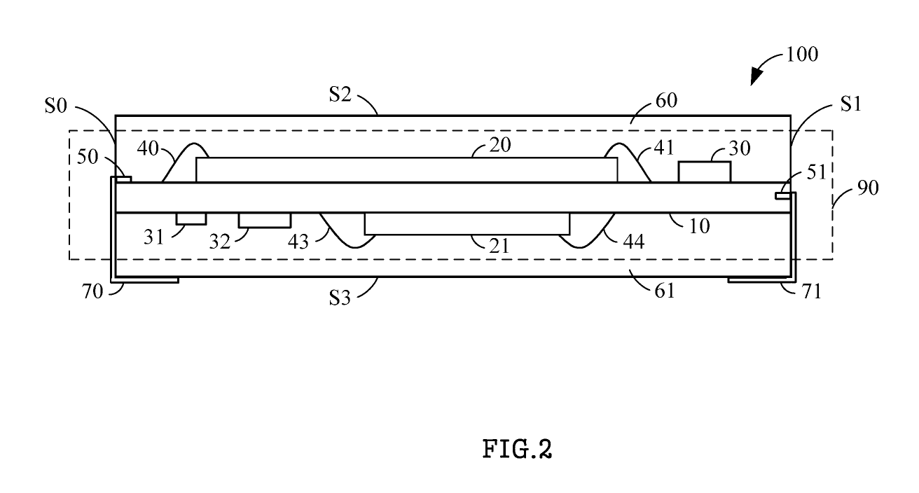

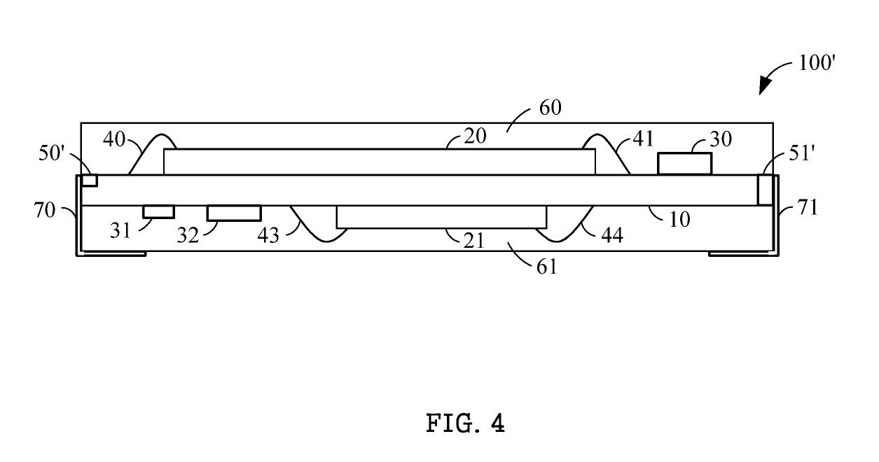

As shown in FIG. 1, the plurality of signal lines 80, 81 and the plurality of input/output ports 50, 51 are disposed on the substrate 10. The plurality of signal lines 80, 81 may be copper foil traces on the substrate 10 to conduct signals of the IC module 90. The plurality of input/output ports 50, 51 are signal input/output ports of the IC module 90, disposed at edges of the substrate 10. In one embodiment, the plurality of input/output ports 50, 51 may be copper foil layer on surfaces of the substrate 10, such as, input/output port 50 shown in FIG. 2. If the substrate 10 is a multilayer PCB, the plurality of input/output ports 50, 51 may be copper foil layer on any layer of the substrate 10. For example, as shown in FIG. 2, the input/output port 50 is on the surface of the substrate 10, and the input/output port 51 is on any middle layer of the substrate 10. In alternative embodiments (as shown in FIG. 4), the plurality of input/output ports 50′, 51′ may be copper pieces embedded in the substrate 10.

The plurality of chips 20, 21 are mounted on the surfaces of the substrate 10, and are connected to the plurality of signal lines 80, 81 and the plurality of input/output ports 50, 51 via the plurality of wires 40, 41, 42, 43, 44. As shown in FIG. 1, the chip 20 is connected to the input/output port 50 via the wire 40 and the signal line 80, and may also be connected to another input/output port via the wire 42. In one embodiment, the plurality of chips 20, 21 are mounted one an upper surface and a lower surface of the substrate 10 (as shown in FIGS. 2 and 4). In alternative embodiments, the plurality of chips 20, 21 may be mounted on the same surface of the substrate 10.

The plurality of passive components 30, 31, 32 are mounted on the surfaces of the substrate 10, and are connected to the plurality of input/output ports 50, 51 via the plurality of signal lines 80, 81. As shown in FIG. 1, the passive component 30 is connected to the chip 20 and the input/output port 51 via the signal line 80 and the wire 41. In one embodiment, the plurality of passive components include resistors, capacitors, and inductors. As shown in FIGS. 2 and 4, the passive component 30 is mounted on the upper surface of the substrate 10, and the passive components 31, 32 are mounted on the lower surface of the substrate 10. In alternative embodiments, the passive components 30, 31, 32 may be mounted on the same surface of the substrate 10.

The plastic encapsulations 60, 61 encapsulates the substrate 10, the plurality of chips 20, 21, the plurality of passive components 30, 31, 32, the plurality of wires 40, 41, 42, 43, 44, the plurality of input/output ports 50, 51 and the plurality of signals lines 80, 81 of the IC module 90. In one embodiment, the plastic encapsulations 60, 61 can be made of epoxide resin. After the IC module 90 is encapsulated by the plastic encapsulations 60, 61, an encapsulation body is formed as shown in FIGS. 2 and 4. The encapsulation body includes side surfaces S0, S1, an upper surface S2, and a lower surface S3. The plurality of input/output ports 50, 51 of the IC module 90 are exposed out of the encapsulation body. In one embodiment, the plurality of input/output ports 50, 51 are exposed out of the side surfaces S0, S1 of the encapsulation body.

The plurality of input/output pins 70, 71 lead the plurality of input/output ports form the side surfaces S0, S1 of the encapsulation body to at least one of the upper surface S2 and the lower surface S3 of the encapsulation body. In one embodiment, the plurality of input/output pins 70, 71 are plated by conductive metal, such as, gold, copper, or nickel. As shown in FIGS. 2 to 4, the plurality of input/output pins 70, 71 are plated on the side surfaces S0, S1 and the lower surface S3, to lead the plurality of input/output ports 50, 51 of the IC module 90 from the side surfaces S0, S1 of the encapsulation body to the lower surface S3 of the encapsulation body to connected to external circuits. In alternative embodiments, the plurality of input/output pins 70, 71 may also be plated on the upper surface S2. In one embodiment, the plurality of input/output pins 70, 71 are directly connected to the plurality of input/output ports 50, 51 of the IC module 90 without solder balls to weld, which avoids soldering problems and improves electrical characteristic of the plurality of input/output pins 70, 71. In addition, the plurality of the input/output pins 70, 71 are directly led from the plurality of input/output ports 50, 51 exposed out of the side surfaces S0, S1 of encapsulation body without solder balls, which avoids influence of sizes the solder balls. Thus, numbers of the input/output pins 70, 71 are greatly increased.

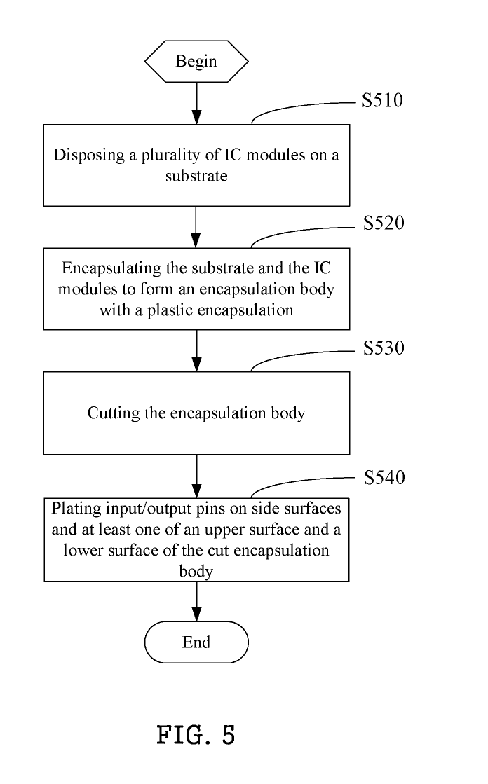

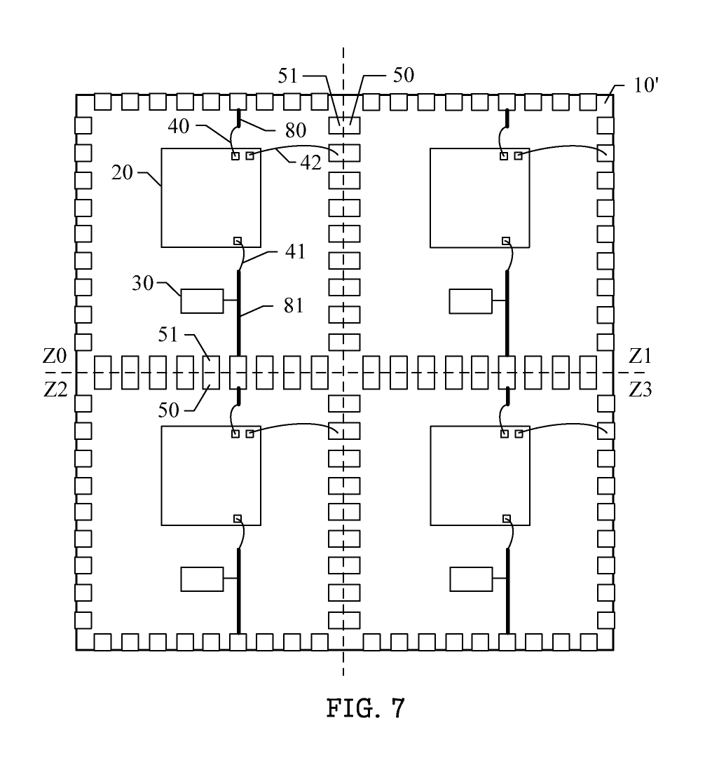

FIG. 5 is a flowchart of one embodiment of an IC package method as disclosed. In step S510, a plurality of IC modules 90 are disposed on a substrate 10′, and the substrate 10′ is divided into a plurality of areas Z0, Z1, Z2, Z3 as shown in FIG. 7. The plurality of IC modules 90 are disposed in each of the plurality of areas Z0, Z1, Z2, Z3. Each of the IC modules 90 of FIG. 7 is similar to that of FIG. 1, therefore, descriptions are omitted here. The plurality of input/output ports 50, 51 of the ICs 90 of neighboring areas are made by a same copper foil layer or copper piece, and are cut in later process to be the plurality of input/output ports 50, 51 of corresponding IC module 90, which improves production efficiency.

In step S520, the plurality of IC modules 90 and the substrate 10′ are encapsulated with a plastic encapsulation to form an encapsulation body. In one embodiment, the plastic encapsulation is made of epoxide resin.

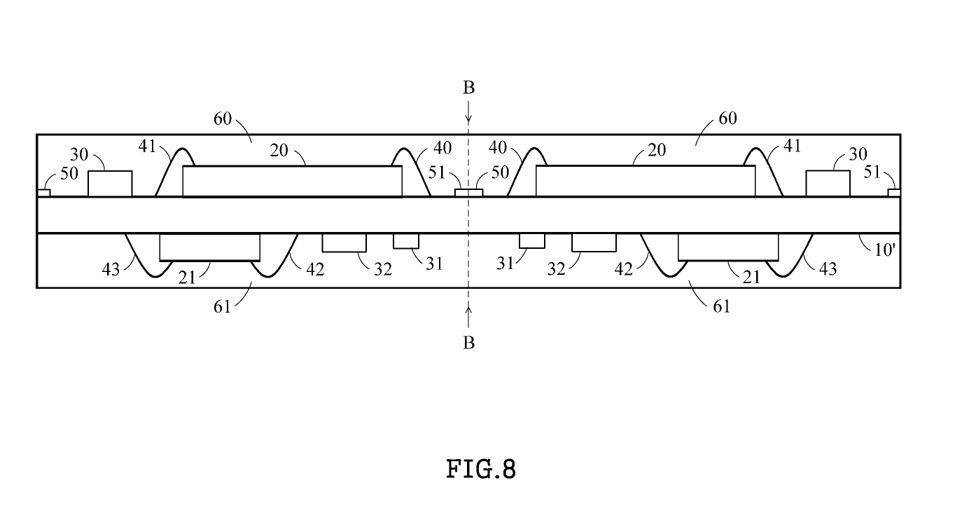

In step S530, the encapsulation body is cut according to the plurality of areas to separate the plurality of IC modules 90. Each cut encapsulation body includes one IC module 90 and is configured with side surfaces S0, S1, an upper surface S2, and a lower surface S3, and also includes the plurality of input/output ports 50, 51 exposed out of the side surfaces S0, S1 of the cut encapsulation body (as shown in FIGS. 2 and 4). As shown in FIG. 8, the encapsulation body is cut along lines B-B, thus, the plurality of input/output ports 50, 51 of the IC modules 90 of the neighboring areas are cut into two parts to be respective input/output ports 50, 51 of corresponding IC module 90.

In step S540, the input/output pins 70, 71 are respectively plated on the side surfaces S0, S1 and the lower surface S3 of each of the cut encapsulation bodies, to correspondingly lead the plurality of input/output ports 50, 51 to the lower surface S3 of the corresponding cut encapsulation body (as shown in FIGS. 2 to 4). In alternative embodiments, the input/output pins 70, 71 may also be plated on the side surfaces S0, S1 and the upper surface S2 of the corresponding cut encapsulation body.

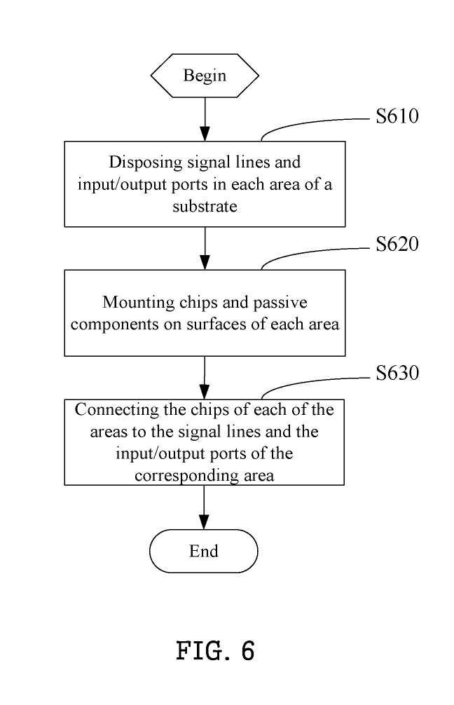

FIG. 6 is a flowchart of one embodiment of step S510 of the IC package method of FIG. 5, that is, a flowchart of respectively disposing a plurality of IC modules 90 on a substrate 10′. In step S610, the plurality of signal lines 80, 81 and the plurality of input/output ports 50, 51 are respectively disposed in each of the plurality of the areas of the substrate 10′. As shown in FIG. 7, the plurality of input/output ports 50, 51 are disposed at edges of each of the plurality of areas of the substrate 10′. In one embodiment, the plurality of input/output ports 50, 51 may be copper foil layer on surfaces of the substrate 10′, such as, input/output port 50 shown in FIG. 2. If the substrate 10′ is a multilayer PCB, the plurality of input/output ports 50, 51 may be copper foil layer on any layer of the substrate 10′. For example, as shown in FIG. 2, the input/output port 50 is on the surface of the substrate 10′, and the input/output port 51 is on any middle layer of the substrate 10′. In alternative embodiments (as shown in FIG. 4), the plurality of input/output ports 50′, 51′ may be copper pieces embedded in the substrate 10′.

In step S620, the plurality of chips 20, 21 are respectively mounted on surfaces of each of the plurality of areas of the substrate 10′. If the IC module 90 includes the passive components 30, 31, 32, the passive components 30, 31, 32 are also mounted on surfaces of each of the plurality of areas of the substrate 10′.

In step S630, the wires 40, 41, 42, 43, 44 respectively connect the plurality of chips 20, 21 of each of the plurality of areas of the substrate 10′ to the plurality of signal lines 80, 81 and the plurality of input/output ports 50, 51 of the corresponding area of the substrate 10′. The plurality of chips 20, 21 are connected to the plurality of input/output ports 50, 51 via the plurality of wires 40, 41, 42, 43, 44 and the plurality of signal lines 80, 81, and are also connected to the plurality of input/output ports 50, 51 only via the plurality of wires 40, 41, 42, 43, 44.

The IC package structure and method utilize the plurality of input/output pins 70, 71 to lead the plurality of input/output ports 50, 51 from the side surfaces of the encapsulation body to the lower or upper surfaces of the encapsulation body, which improves electrical characteristic of the input/output pins of the IC package structure and increases amounts of the input/output pins on surfaces of the IC package structure.

The foregoing disclosure of various embodiments has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto and their equivalents.

What is claimed is:

1. An integrated circuit package structure, comprising:
an integrated circuit module, comprising:
a substrate, comprising a plurality of signal lines and a plurality of input/output ports disposed at edges of the substrate;
a plurality of chips, mounted on surfaces of the substrate; and
a plurality of wires, to connect the plurality of chips to the plurality of signals lines and the plurality of input/output ports;
an encapsulation body, to encapsulate the integrated circuit module, the encapsulation body comprising an upper surface, a lower surface, and side surfaces, wherein the plurality of input/output ports are exposed out of the encapsulation body; and
a plurality of input/output pins, disposed on the side surfaces and at least one of the upper surface and the lower surface of the encapsulation body to correspondingly lead the plurality of input/output ports to the at least one of the upper surface and the lower surface of the encapsulation body.

2. The integrated circuit package structure of claim 1, wherein the integrated circuit module comprises a plurality of passive components mounted on the surfaces of the substrate.

3. The integrated circuit package structure of claim 1, wherein the plurality of input/output ports are copper foil layer on the surfaces of the substrate.

4. The integrated circuit package structure of claim 1, wherein the substrate is a multilayer printed circuit board, and the plurality of input/output ports are copper foil layer on any layer of the substrate.

5. The integrated circuit package structure of claim 1, wherein the plurality of input/output ports are copper pieces embedded in the substrate.

6. The integrated circuit package structure of claim 1, wherein the encapsulation body is a plastic encapsulation body.

7. An integrated circuit package method, comprising:
disposing a plurality of integrated circuit modules on a substrate;
encapsulating the substrate and the plurality of integrated circuit modules to form an encapsulation body;
cutting the encapsulation body, wherein each cut encapsulation body comprises one of the integrated circuit modules and is configured with an upper surface, a lower surface, and side surfaces, and also comprises input/output ports exposed out of the corresponding cut encapsulation body; and
respectively plating a plurality of input/output pins on the side surfaces and at least one of the upper surface and the lower surface of the plurality of cut encapsulation bodies to correspondingly lead the plurality of input/output ports to the at least one of the upper surface and the lower surface of the corresponding one of the plurality of cut encapsulation body.

8. The integrated circuit package method of claim 7, wherein respectively disposing a plurality of integrated circuit modules on a substrate comprises:
respectively disposing a plurality of signal lines and a plurality of input/output ports in each of a plurality of areas of the substrate, wherein the plurality of input/output ports are disposed at edges of each of the plurality of areas of the substrate;
respectively mounting a plurality of chips on surfaces of each of the plurality of areas of the substrate; and
respectively connecting the plurality of chips of each of the plurality of areas of the substrate to the plurality of signal lines and input/output ports of corresponding area of the substrate via wires.

9. The integrated circuit package method of claim 8, wherein respectively disposing a plurality of integrated circuit modules on a substrate further comprises respectively mounting a plurality of passive components on the surfaces of each of the plurality of areas of the substrate.

10. The integrated circuit package method of claim 7, wherein the plurality of input/output ports are copper foil layer on the surfaces of the substrate.

11. The integrated circuit package method of claim 7, wherein the substrate is a multilayer printed circuit board, and the plurality of input/output ports are copper foil layer on any layer of the substrate.

12. The integrated circuit package method of claim 7, wherein the plurality of input/output ports are copper pieces embedded in the substrate.

13. The integrated circuit package method of claim 7, wherein the encapsulation body is a plastic encapsulation body.
